(19) United States
(12) Patent Application Publication
(10) Pub. No.: US 2005/0242371 A1
(43) Pub. Date: Nov. 3, 2005

(54) High current MOS device with avalanche protection and method of operation

(76) Inventors: Vishnu K. Khemka, Phoenix, AZ (US); Amitava Bose, Tempe, AZ (US); Vijay Parthasarathy, Phoenix, AZ (US); Ronghua Zhu, Chandler, AZ (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/836,730

(22) Filed: Apr. 30, 2004

(51) Int. Cl. H01L 31/113

(52) U.S. Cl. 257/175

(57) ABSTRACT

Particularly in high current applications, impact ionization induced electron-hole pairs are generated in the drain of an MOS transistor that can cause a parasitic bipolar transistor to become destructively conductive. The holes pass through the body region of the MOS transistor, which has intrinsic resistance, to the source, which is typically held at a relatively low voltage, such as ground. The hole current causes a voltage to develop in the body region, which acts as the base. This increased base voltage is what can cause the parasitic bipolar transistor to become conductive. The likelihood of this is greatly reduced by developing a voltage between the source, which acts as the emitter, and the body region by passing the channel current through an impedance between the source and the body region. This causes the emitter voltage to increase as the base voltage is increased and thereby prevent the parasitic bipolar transistor from becoming conductive.

### BACKGROUND

The present disclosure relates generally to semiconductors, and more particularly to a high current MOS device with avalanche protection and method of operation.

### RELATED ART

Energy capability is of high interest with respect to the continuous size shrinking of power devices. Actually, the sizes of power MOS devices may no longer be limited by the on-resistance but instead be limited by the energy capability. For automotive applications, the energy requirements imposed on power MOS devices can cause device temperatures to rise dramatically which can sometimes causes corresponding devices to fail electrically via snapback. In addition, an inherent parasitic bipolar transistor in a power MOS device causes the particular device to fail electro-thermally, preventing it from achieving a pure thermal limit of the device.

FIG. 1 is a cross-section view of an LDMOSFET device 10 according to the Prior Art. LDMOSFET device 10 includes a P-type substrate 12, an N-Well region 14, a P Body region 16, N+ diffusions 18 and 20, and a P+ diffusion region 22. Note that the N+ diffusion 20 overlaps with P+ diffusion region 22 to a limited extent. The N+ diffusion 18 and the N-Well 14 make up the drain region. The N+ diffusion 20 and P+ diffusion 22 make up the source region of device 10. P+ diffusion region 22 provides contact to the P Body region 16.

LDMOSFET device 10 further includes an oxide isolation region 24, a dielectric 26 (including a gate dielectric underneath gate electrode 28), and gate electrode 28. LDMOSFET device 10 further includes electrical contacts 30 and 32 (for example, some type of silicide) for drain and source regions, respectively. Note that the source contact region 32 spans over and couples to the N+ diffusion region 20 and the P+ body contact region 22. A conductive material, indicated by reference numerals 34 and 36, couples the drain and source regions, respectively to a top of the device 10.

A disadvantage of the LDMOSFET device 10 is that it also includes an inherent parasitic bipolar transistor 38. Parasitic bipolar transistor 38 includes collector 40 (corresponding to N-Well 40 and N+ diffusion 18), base 42 (corresponding to P Body region 16), and emitter 44 (corresponding to N+ diffusion 20), as well as, a resister element 46 disposed between base 42 and emitter 44, designated as RBI (corresponding to a portion of the P body region 16 extending along a lateral dimension of the N+ diffusion region 20 within the P body region 16). Emitter 44 is effectively coupled to both the P+ body contact 22 and the N+ diffusion region 20. During operating conditions of high current conduction and high drain-to-source voltage, parasitic bipolar transistor 38 can cause device 10 to fail electro-thermally, preventing device 10 from achieving its pure thermal limit.

What is needed is an improved high current MOS device and method for overcoming the problems discussed above.

### SUMMARY

According to one embodiment, a semiconductor device includes a substrate, an active region in the substrate having a P-type background doping and having a top surface, a P body region having a first P level, an N-type region formed in the P body region at the top surface and forming a first boundary of a channel of the transistor, an N drift region spaced from the P body region and forming a second boundary of the channel, and an impedance coupled between the P body region and the N-type region formed in the P body region.

### BRIEF DESCRIPTION OF THE DRAWINGS

The embodiments of the present disclosure are illustrated by way of example and not limited by the accompanying figures, in which like references indicate similar elements, and in which:

FIG. 1 is a cross-section view of an LDMOSFET according to the Prior Art;

FIG. 2 is schematic view diagram of a composite LDMOSFET including an impedance according to one embodiment of the present disclosure;

FIG. 3 is schematic view diagram of a composite LDMOSFET including a zener diode according to one embodiment of the present disclosure;

FIG. 4 a cross-section view of the composite LDMOSFET of FIG. 3 including a zener diode according to one embodiment of the present disclosure;

FIG. 5 is schematic view diagram of a composite LDMOSFET including a resistive element according to one embodiment of the present disclosure;

FIG. 6 a cross-section view of the composite LDMOSFET of FIG. 5 including a resistive element internal to the composite LDMOSFET device according to one embodiment of the present disclosure;

FIG. 7 a cross-section view of the composite LDMOSFET of FIG. 5 including a resistive element external to the composite LDMOSFET device according to one embodiment of the present disclosure;

FIG. 8 is a graphical representation view of power in watts versus drain-to-source voltage in volts, comparing power handling capability of a known LDMOSFET and the composite LDMOSFET of the present disclosure at a first temperature on the order of 25 degrees Celcius and at a second temperature at 150 degrees Celcius; and

FIG. 9 is a graphical representation view of power dissipation in watts versus temperature in Celcius, comparing power handling capability of a known LDMOSFET with a body/source short and the composite LDMOSFET of the present disclosure with body/source separate.

Skilled artisans appreciate that elements in the figures are illustrated for simplicity and clarity and have not necessarily been drawn to scale. For example, the dimensions of some of the elements in the figures may be exaggerated relative to other elements to help improve an understanding of the embodiments of the present disclosure.

### DETAILED DESCRIPTION

In high current applications, electron-hole pairs are generated in the drain of an MOS transistor that can cause an inherent parasitic bipolar transistor to become destructively conductive. The holes pass through the body region of the MOS transistor, which has intrinsic resistance, to the source, which is typically held at a relatively low voltage, such as ground. The hole current causes a voltage to develop in the body region, which acts as the base. This increased base voltage is what can cause the parasitic bipolar transistor to become conductive. The likelihood of this is greatly reduced by developing a voltage between the source, which acts as the emitter, and the body region by passing the channel current through an impedance between the source and the body region. This causes the emitter voltage to increase as the base voltage is increased and thereby prevent the parasitic bipolar transistor from becoming conductive.

Accordingly, in order to realize the true thermal capability of a power LDMOSFET device, the inherent parasitic bipolar transistor of the LDMOSFET device needs to be deactivated. Deactivating the inherent parasitic bipolar transistor removes the electrical influence on the power dissipation capability of the LDMOSFET device. In one embodiment, the source contact is left floating, and a resistor or a low-voltage zener diode is placed in between the source and the body contact. In addition, the body contact is treated as the effective source terminal of the finalized device.

With the embodiments of the present disclosure, as current flows through the LDMOSFET device, the current creates a reverse bias across the source to body junction, thus preventing the inherent parasitic bipolar transistor from turning on in the event of an energy capability test. Furthermore, energy capability can be improved by as much as 40% over that of the prior known devices.

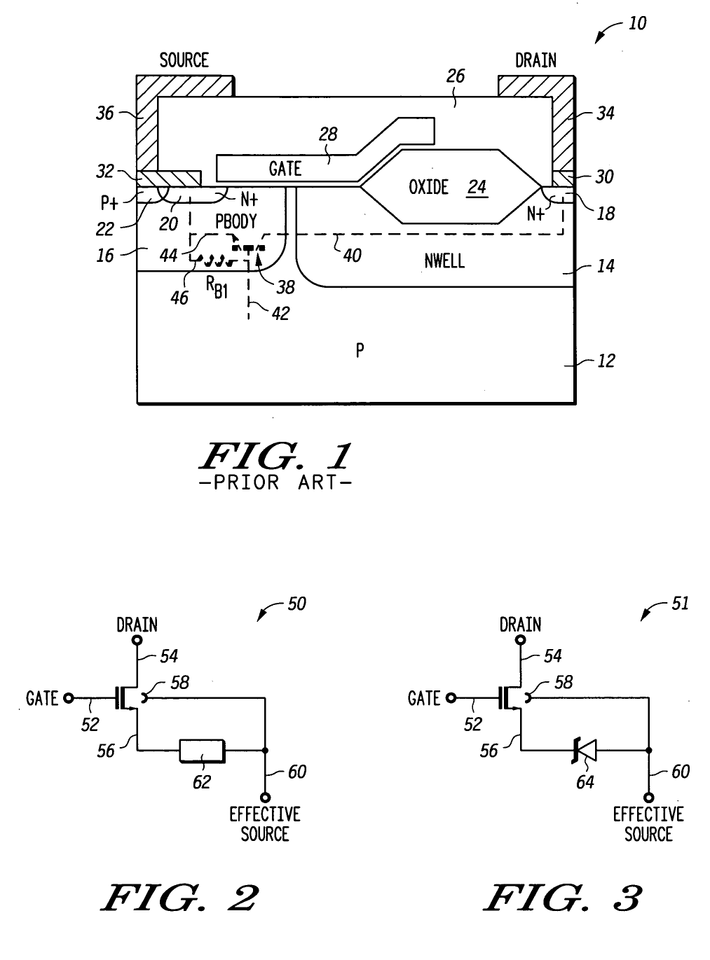

With reference again to the figures, FIG. 2 is schematic view diagram of a composite LDMOSFET 50 including an impedance 62 according to one embodiment of the present disclosure. Composite LDMOSFET 50 includes a gate 52, drain 54, and source 56. LDMOSFET 50 further includes a body contact 58 separate from source 56, wherein body contact 58 couples to an effective source 60 of device 50. An impedance 62 couples the true source 56 to the body contact 58 for enabling the effective source 60. Impedance 62 can include an active impedance or a passive impedance, as may be required for a particular LDMOSFET implementation.

FIG. 3 is schematic view diagram of a composite LDMOSFET 51 including a zener diode 64 according to one embodiment of the present disclosure. Composite LDMOSFET 51 includes a gate 52, drain 54, and source 56. LDMOSFET 51 further includes a body contact 58 separate from source 56, wherein body contact 58 couples to an effective source 60 of device 51. A zener diode 64 couples the true source 56 to body contact 58 for enabling the effective source 60, further as discussed herein.

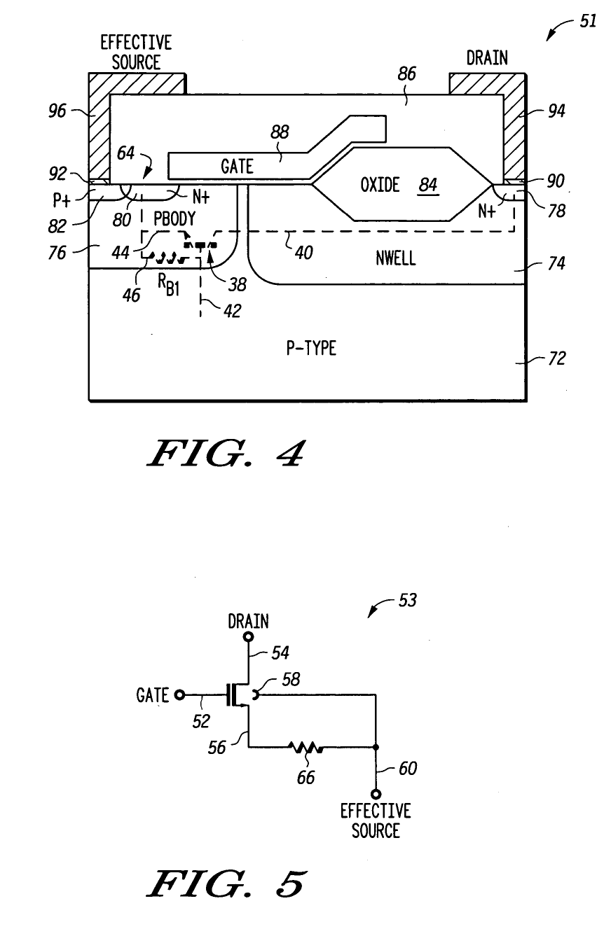

FIG. 4 a cross-section view of the composite LDMOSFET 51 of FIG. 3 including a zener diode 64 according to one embodiment of the present disclosure. LDMOSFET device 51 includes a P-type substrate 72, an N-Well region 74, a P Body region 76, N+ diffusions 78 and 80, and a P+ diffusion region 82. Note that the N+ diffusion 80 overlaps with P+ diffusion region 82 to a limited extent. Furthermore, the N+ diffusion 78 and the N-Well 74 make up the drain region of LDMOSFET 51. The N+ diffusion 80 makes up a true source region of LDMOSFET device 51.

Note again that the N+ diffusion 80 overlaps with P+ diffusion region 82 to a limited extent. Further note that in the absence of an overlying electrical contact touching both regions together, the combination of N+ diffusion region 80 overlapping with the P+ diffusion region 82 to a limited extent forms a zener diode (as indicated by reference numeral 64 of FIG. 3). Zener diode 64 couples the true source 80 to the body contact 82 for enabling the effective source (as indicated by reference numeral 60 of FIG. 3). In addition, P+diffusion region 82 provides contact to the P Body region 76 (as indicated by reference numeral 58 of FIG. 3).

With reference still to FIG. 4, LDMOSFET device 51 further includes an oxide isolation region 84, a dielectric 86 (including a gate dielectric underneath gate electrode 88), and gate electrode 88. LDMOSFET device 51 further includes electrical contacts 90 and 92 (for example, any suitable silicide) for the drain and effective source regions, respectively. Note that electrical contact 92 is fully contained within a region overlying P+ diffusion 82. In other words, the electrical contact 92 does not span over, nor couple with, the N+ diffusion region 80 (corresponding to the true source of device 51). Accordingly, electrical contact 92 does not interfere with zener diode 64. In addition, a conductive material, indicated by reference numerals 94 and 96, is provided for coupling the drain and effective source regions, respectively, to a top surface of the device 51.

An advantage of the LDMOSFET device 51 of FIG. 4 is that, while it also includes an inherent parasitic bipolar transistor 38, the device power handling capability is dramatically improved over the embodiment of FIG. 1. The parasitic bipolar transistor 38 includes a collector 40 (corresponding to N-Well 74 and N+ diffusion 78), base 42 (corresponding to P Body region 76), and emitter 44 (corresponding to N+ diffusion 80), as well as, a resister element 46 disposed between base 42 and emitter 44, designated as RBI (corresponding to a portion of the P body region 76 extending along a lateral dimension of the N+ diffusion region 80 within the P body region 76). Emitter 44 is effectively coupled to the P+ body contact 82 via zener diode 64.

During operating conditions of high current conduction and high drain-to-source voltage with LDMOSFET device 51, zener diode 64 creates a reverse bias between the base 42 and emitter 44 regions of the parasitic bipolar transistor 38. The reverse bias prevents the parasitic bipolar transistor 38 from becoming conductive prematurely. In other words, the reverse bias suppresses a turn on of the parasitic bipolar transistor 38. The reverse bias delays the parasitic bipolar transistor 38 becoming conductive prematurely, thus suppressing a turn on of the same, which, in response to becoming conductive, would have caused device 51 to fail electro-thermally. Accordingly, the reverse bias provided by zener diode 64 makes it possible for device 51 to achieve a power handling capability substantially close to its pure thermal limit.

FIG. 5 is schematic view diagram of a composite LDMOSFET device 53 including a resistive element 66 according to one embodiment of the present disclosure. Composite LDMOSFET 53 includes a gate 52, drain 54, and source 56. LDMOSFET 53 further includes a body contact 58 separate from source 56, wherein body contact 58 couples to an effective source 60 of device 53. A resistive element 66 couples the true source 56 to body contact 58 for enabling the effective source 60, as discussed further herein.

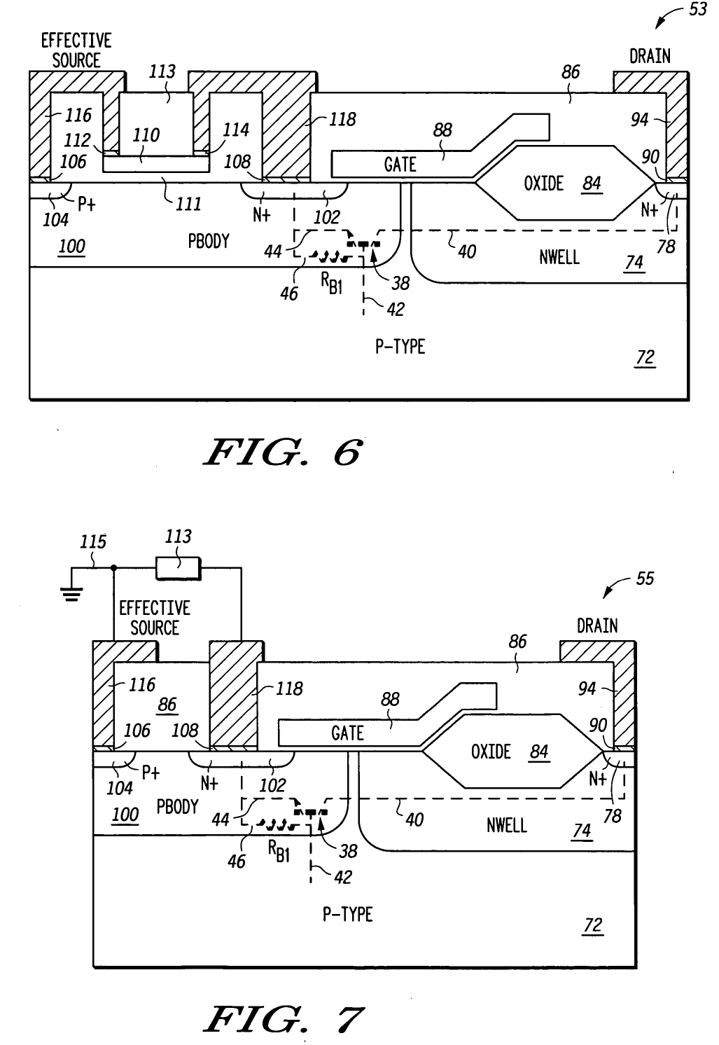

FIG. 6 a cross-section view of the composite LDMOSFET 53 of FIG. 5 including a resistive element 66 internal to the composite LDMOSFET device according to one embodiment of the present disclosure. LDMOSFET device 53 includes a P-type substrate 72, an N-Well region 74, a P Body region 100, N+ diffusions 78 and 102, and a P+ diffusion region 104. Note that the N+ diffusion 102 does not overlap with P+ diffusion region 104, but is spaced apart there from by a predetermined spacing. The N+ diffusion 78 and the N-Well 74 make up the drain region of LDMOSFET 53. The N+ diffusion 102 makes up a true source region of LDMOSFET 53.

Note again that the N+ diffusion 102 does not overlap with P+ diffusion region 104, but is spaced apart there from by a predetermined spacing. However, resistive element 110 is provided, wherein resistive element couples the true source 102 to the body contact 104 for enabling the effective source (as indicated by reference numeral 60 of FIG. 5). Note that in the embodiment of FIG. 6, resistive element 110 is internal to LDMOSFET device 53. In addition, P+ diffusion region 104 provides contact to the P Body region 100 (as indicated by reference numeral 58 of FIG. 5).

With reference still to FIG. 6, LDMOSFET device 53 further includes an oxide isolation region 84, a dielectric 86 (including a gate dielectric underneath gate electrode 88), and gate electrode 88. LDMOSFET device 53 further includes electrical contacts 90 and 106 (for example, any suitable silicide) for drain and effective source regions, respectively. Note that electrical contact 106 can be fully contained within a region overlying P+ diffusion 104. In other words, the electrical contact 106 does not span over, nor couple with, the N+ diffusion region 102 (corresponding to the true source of device 53). In addition, a conductive material, indicated by reference numerals 94 and 116, is provided for coupling the drain and effective source regions, respectively, to a top of the device 53.

Referring still to FIG. 6, additional electrical contacts 108, 112, and 114 are provided. Conductive material 116 couples one end of resistive element 110 to a top of the device 53, via electrical contact 112. Conductive material 118 couples another end of resistive element 110 to a top of the device 53 via electrical contact 114 and also couples true source 102 to a top of the device 53 via electrical contact 108.

FIG. 7 a cross-section view of the composite LDMOSFET of FIG. 5 including a resistive element 113 external to the composite LDMOSFET device 55 according to one embodiment of the present disclosure. The embodiment of FIG. 7 is similar to that of FIG. 6, with the following differences. Conductive material 116 couples to a top of the LDMOSFET device 55 and to one end of external resistive element 113. Accordingly, conductive material 116 couples to the effective source of device 55. Conductive material 118 couples true source 102 to a top of the device 55 via electrical contact 108. Conductive material further couples to another end of external resistive element 113.

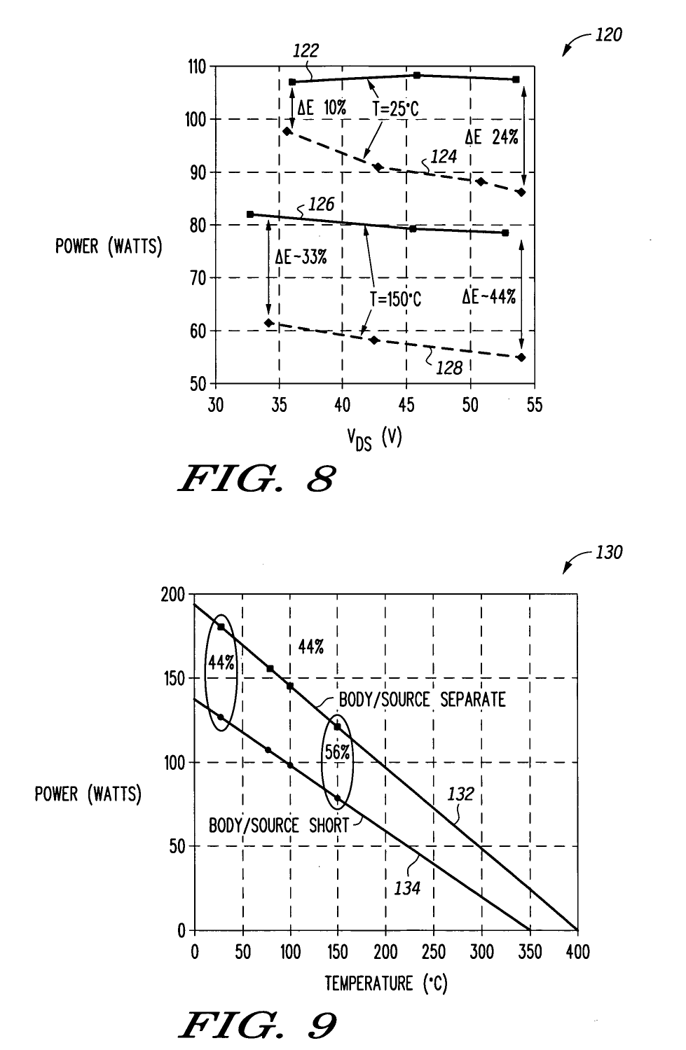

FIG. 8 is a graphical representation view of power in watts versus drain-to-source voltage in volts, comparing power handling capability of a known LDMOSFET and the composite LDMOSFET according to one embodiment of the present disclosure at a first temperature on the order of 25 degrees Celcius and at a second temperature at 150 degrees Celcius. With respect to curves 122 and 124, for low temperature operation at 25 degrees Celcius, curve 122 represents power handling capability of the composite LDMOSFET according to one embodiment of the present disclosure and curve 124 represents power handling capability of a known LDMOSFET device. For VDS on the order of approximately 36 volts at 25° C., the delta power (or energy differential) is on the order of approximately ten percent (10%). For VDS on the order of approximately 54 volts at 25° C., the delta power (or energy differential) is on the order of approximately twenty four percent (24%).

Referring still to FIG. 8, with respect to curves 126 and 128, for high temperature operation at 150 degrees Celcius, curve 126 represents power handling capability of the composite LDMOSFET according to one embodiment of the present disclosure and curve 128 represents power handling capability of a known LDMOSFET device. For VDS on the order of approximately 34 volts at 150° C., the delta power (or energy differential) is on the order of approximately thirty three percent (33%). For VDS on the order of approximately 54 volts at 150° C., the delta power (or energy differential) is on the order of approximately twenty four percent (44%). Accordingly, there is a clear improvement in energy capability at low and high temperatures. In addition, temperature measured at the center of an LDMOSFET device according to one embodiment of the present disclosure during failure testing increased from 650K to 720K, which provides some explanation for the significant increase in energy.

FIG. 9 is a graphical representation view of power dissipation in watts versus temperature in Celcius, comparing power handling capability of a known LDMOSFET with a body/source short and the composite LDMOSFET of the present disclosure with body/source separate. With respect to curves 132 and 134, curve 132 represents power handling capability of the composite LDMOSFET according to one embodiment of the present disclosure, wherein the body contact and true source are separate (i.e., not in direct contact with one another). Curve 134 represents power handling capability of a known LDMOSFET device, wherein the body contact and source are shorted together (i.e., in direct contact with one another). For low temperature operation on the order of 25° C., the delta power (or energy differential) is on the order of approximately forty-four percent (44%). For high temperature operation on the order of 150° C., the delta power (or energy differential) is on the order of approximately fifty six percent (56%).

Accordingly, one embodiment of the semiconductor device includes a substrate, an active region in the substrate having a P-type background doping and having a top surface, a P body region having a first P level, an N-type region formed in the P body region at the top surface and forming a first boundary of a channel of the transistor, an N drift region spaced from the P body region and forming a second boundary of the channel, and an impedance coupled between the P body region and N-type region formed in the P body region. The P body region has an intrinsic resistance. When high current passes through the channel, the N body region generates electron-hole pairs. At least some of the holes of the electron-hole pairs pass through the P body region causing a voltage drop in the P body region. Current that passes through the channel passes through the impedance and thereby causes a reverse bias between the source region and the P body region to offset the voltage drop in the P body region.

In another embodiment, a MOS transistor having a parasitic bipolar transistor includes a first body region of a first conductivity type having a channel of the MOS transistor and having an intrinsic resistance. The first body region is a base of the parasitic bipolar transistor. The MOS transistor further includes a source region adjoining the channel and being an emitter of the parasitic bipolar transistor. A drain region adjoins the channel region and is a collector of the parasitic transistor. In addition, an impedance is coupled between the first body region and the source region. The drain region generates electron-hole pairs in response to a high current in the channel. At least some of the holes of the electron hole pairs pass through the first body region to the source region and cause a voltage increase on the base of the parasitic bipolar transistor. The current passing through the channel passes through the impedance. Lastly, the impedance develops enough voltage on the emitter of the parasitic transistor to prevent the parasitic bipolar transistor from becoming conductive.

In yet another embodiment, a method of operating a transistor having a gate, a drain, a source, and a channel inside a body region, comprises the following. A high current is driven from the drain to the source through the channel. Electron-hole pairs are generated in the drain in response to the high current in the channel. At least some of the holes of the electron-hole pairs pass through the first body region to the source region to cause a voltage differential in the body region. Lastly, a voltage differential is generated between the source and the body region to offset the voltage differential in the body region, wherein the generating comprises passing the high current through an impedance that is connected between the source and the body region.

In the foregoing specification, the disclosure has been described with reference to various embodiments. However, one of ordinary skill in the art appreciates that various modifications and changes can be made without departing from the scope of the present embodiments as set forth in the claims below. For example, the embodiments herein can be part of an integrated circuit. Accordingly, the specification and figures are to be regarded in an illustrative rather than a restrictive sense, and all such modifications are intended to be included within the scope of the present embodiments.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the term “comprises,” “comprising,” or any other variation thereof, are intended to cover a non-exclusive inclusion, such that a process, method, article, or apparatus that comprises a list of elements does not include only those elements by may include other elements not expressly listed or inherent to such process, method, article, or apparatus.

1. A semiconductor device, comprising:
a substrate;
an active region in the substrate having a P-type background doping and having a top surface;
a P body region having a first P level;
an N-type region formed in the P body region at the top surface and forming a first boundary of a channel of the transistor;
an N drift region spaced from the P body region and forming a second boundary of the channel; and
an impedance coupled between the P body region and the N-type region formed in the P body region.

2. The semiconductor device of claim 1, further comprising a heavily-doped region of the N-type in the N drift region for being a drain contact.

3. The semiconductor device of claim 1, wherein:
the P body region has an intrinsic resistance;
responsive to high current passing through the channel, the N drift region generates electron-hole pairs;
at least some of the holes of the electron-hole pairs pass through the P body region causing a voltage drop in the P body region; and
wherein the current that passes through the channel passes through the impedance and thereby causes a reverse bias between the source region and the P body region to offset the voltage drop in the P body region.

4. The semiconductor device of claim 3, wherein the impedance comprises a resistor.

5. The semiconductor device of claim 3, wherein the impedance comprises a zener diode.

6. The semiconductor device of claim 1, wherein the P body region has a doping concentration greater than the P-type background doping.

7. The semiconductor device of claim 6, further comprising a heavily-doped region of the P-type in the P body region for making contact between the impedance and the P body region.

8. The semiconductor device of claim 1 characterized as being part of an integrated circuit in which the impedance is external to the integrated circuit.

9. The semiconductor device of claim 1 characterized as being part of an integrated circuit in which the impedance is internal to the integrated circuit.

10. A MOS transistor having a parasitic bipolar transistor, comprising:
a first body region of the first conductivity type having a channel of the MOS transistor and having an intrinsic resistance, wherein the first body region is a base of the parasitic bipolar transistor;
a source region of the MOS transistor adjoining the channel and being an emitter of the parasitic bipolar transistor;
a drain region adjoining the channel region and being a collector of the parasitic transistor; and
an impedance coupled between the first body region and the source region.

11. The MOS transistor of claim 10, wherein:
the drain region generates electron-hole pairs in response to a high current in the channel;
at least some of the holes of the electron hole pairs pass through the first body region to the source region and cause a voltage increase on the base of the parasitic bipolar transistor;
the current passing through the channel passes through the impedance; and
the impedance develops enough voltage on the emitter of the parasitic transistor to prevent the parasitic bipolar transistor from becoming conductive.

12. The semiconductor device of claim 11, wherein the impedance comprises a resistor.

13. The semiconductor device of claim 11, wherein the impedance comprises a zerner diode.

14. The semiconductor device of claim 11, further comprising a heavily-doped region of the first conductivity type in the first body region for making contact between the impedance and the first body region.

15. The semiconductor device of claim 11 characterized as being part of an integrated circuit in which the impedance is external to the integrated circuit.

16. The semiconductor device of claim 11 characterized as being part of an integrated circuit in which the impedance is internal to the integrated circuit.

17. The semiconductor device of claim 11 wherein the first conductivity type is P-type.

18. An integrated circuit having a MOS transistor, comprising:
a substrate;
an active region in the substrate having a top surface;
a first body region having a channel of the MOS transistor and being of the first conductivity type;
a source region of the MOS transistor adjoining the channel and of the second conductivity type;
a drain region adjoining the channel region and of the second conductivity type;
a first terminal for receiving a first connection external to the integrated circuit and connected to the first body region; and
a second terminal for receiving a second connection external to the integrated circuit and connected to the source region.

19. The MOS transistor of claim 18, further comprising an impedance coupled between the first terminal and the second terminal, wherein:
the drain region generates electron-hole pairs in response to a high current in the channel;
at least some of the holes of the electron hole pairs pass through the first body region to the source region and cause a voltage differential in the first body region;
the current passing through the channel passes through the impedance; and
the impedance develops a voltage to offset the voltage differential in the first body region.

20. The semiconductor device of claim 19, wherein the impedance comprises a resistor.

21. The semiconductor device of claim 19, wherein the impedance comprises a zerner diode.

22. The semiconductor device of claim 19, further comprising a heavily-doped region of the first conductivity type in the first body region for making contact between the impedance and the first body region.

23. The semiconductor device of claim 18 wherein the MOS transistor is an N channel transistor.

24. An integrated circuit having a MOS transistor, comprising:
a substrate;
an active region in the substrate having a top surface;
a first body region having a channel of the MOS transistor, the first body region at the top surface;
a source region of the MOS transistor adjoining the channel, the source region at the top surface;
a drain region of the MOS transistor adjoining the channel region, the drain region at the top surface; and
impedance means for coupling an impedance between the source and the first body region.

25. The integrated circuit of claim 24, wherein the impedance means comprises:
a first terminal for receiving a first connection external to the integrated circuit and connected to the first body region; and
a second terminal for receiving a second connection external to the integrated circuit and connected to the source region.

26. The integrated circuit of claim 25, further comprising a resistor between the first terminal and the second terminal.

27. The integrated circuit of claim 25, further comprising a zener diode between the first terminal and the second terminal.

28. The integrated circuit of claim 24, wherein the impedance means comprises:
a first connection internal to the integrated circuit for connecting a first terminal of an impedance to the first body region; and
a second connection internal to the integrated circuit for connecting a first terminal of the impedance to the source region.

29. The integrated circuit of claim 28, further comprising a resistor between the first connection and the second connection.

30. The integrated circuit of claim 28, further comprising a zener diode between the first connection and the second connection.

31. The MOS transistor of claim 24, further comprising the impedance coupled between the source and the first body region, wherein:
the drain region generates electron-hole pairs in response to a high current in the channel;
at least some of the holes of the electron hole pairs pass through the first body region to the source region and cause a voltage differential in the first body region;
the current passing through the channel passes through the impedance; and
the impedance develops a voltage to offset the voltage differential in the first body region.

32. The MOS transistor of claim 24, wherein the body region is connected to ground and the impedance means is for generating a voltage differential between the source region and ground.

33. A method of operating a transistor having a gate, a drain, a source, and a channel inside a body region, comprising:
driving a high current from the drain to the source through the channel;
generating electron-hole pairs in the drain in response to the high current in the channel;
passing at least some of the holes of the electron-hole pairs through the first body region to the source region to cause a voltage differential in the body region; and
generating a voltage differential between the source and the body region to offset the voltage differential in the body region.

34. The method of claim 33, wherein the generating comprises passing the high current through an impedance that is connected between the source and the body region.
